(19) United States
(12) Patent Application Publication
(10) Pub. No.: US 2021/0031243 A1
(43) Pub. Date: Feb. 4, 2021

(54) METHODS AND APPARATUS FOR CLEANING SUBSTRATES

(71) Applicant: ACM Research (Shanghai) Inc., Shanghai (CN)

(72) Inventors: Hui Wang, Shanghai (CN); Xi Wang, Shanghai (CN); Xiaoyan Zhang, Shanghai (CN); Fufa Chen, Shanghai (CN)

(73) Assignee: ACM Research (Shanghai) Inc., Shanghai (CN)

(21) Appl. No.: 16/964,507

(22) PCT Filed: Jan. 23, 2018
(86) PCT No.: PCT/CN2018/073723

§ 371 Date: Jul. 23, 2020

(51) Int. Cl. B08B 3/12; H01L 21/02; H01L 21/67

(52) U.S. Cl. CPC B08B 3/12; H01L 21/67051; H01L 21/02057

(57) ABSTRACT

A substrate (2010, 3010, 4010, 5010, 6010, 7010, 8010) cleaning method is provided, it comprises the steps of: placing a substrate (2010, 3010, 4010, 5010, 6010, 7010, 8010) on a substrate holder (1314); delivering cleaning liquid onto the surface of the substrate (2010, 3010, 4010, 5010, 6010, 7010, 8010); implementing a pre-treatment process to detach bubbles (2050, 2052, 3050, 4050, 5050, 6050, 7052, 70584, 7056, 8052, 8054, 8056) from the surface of the substrate (2010, 3010, 4010, 5010, 6010, 7010, 8010); and then implementing an ultra or mega sonic cleaning process for cleaning the substrate (2010, 3010, 4010, 5010, 6010, 7010, 8010).

### FIELD OF THE INVENTION

The present invention generally relates to method and apparatus for cleaning substrate. More particularly, relates to detaching bubbles from the surface of the substrate to avoid bubbles damaging implosion during the cleaning process, so as to remove fine particles more efficiently in patterned structures on the substrate.

### BACKGROUND

Semiconductor devices are manufactured or fabricated on semiconductor substrates using a number of different processing steps to create transistor and interconnection elements. Recently, the transistors are built from two dimensions to three dimensions such as finFET transistors and 3D NAND memory. To electrically connect transistor terminals associated with the semiconductor substrate, conductive (e.g., metal) trenches, vias, and the like are formed in dielectric materials as part of the semiconductor device. The trenches and vias couple electrical signals and power between transistors, internal circuit of the semiconductor devices, and circuits external to the semiconductor device.

In forming the finFET transistors and interconnection elements on the semiconductor substrate may undergo, for example, masking, etching, and deposition processes to form the desired electronic circuitry of the semiconductor devices. In particular, multiple masking and plasma etching step can be performed to form a pattern of finFET, 3D NAND flash cell and or recessed areas in a dielectric layer on a semiconductor substrate that serve as fin for the transistor and or trenches and vias for the interconnection elements. In order to removal particles and contaminations in fin structure and or trench and via post etching or photo resist ashing, a wet cleaning step is necessary. Especially, when device manufacture node migrating to 14 or 16 nm and beyond, the side wall loss in fin and or trench and via is crucial for maintaining the critical dimension. In order to reduce or eliminate the side wall loss, it is important to use moderate, dilute chemicals, or sometime de-ionized water only. However, the dilute chemical or de-ionized water usually is not efficient to remove the particles in the fin structure, 3D NAND hole and or trench and via. Therefore the mechanical force such as ultra or mega sonic is needed in order to remove those particles efficiently. Ultra sonic or mega sonic wave will generate bubble cavitation which applies mechanical force to substrate structure, the violent cavitation such as transit cavitation or micro jet will damage those patterned structures. To maintain a stable or controlled cavitation is key parameters to control the mechanical force within the damage limit and at the same time efficiently to remove the particles.

FIG. 1A and FIG. 1B depict a transit cavitation damaging patterned structures 1030 on a substrate 1010 during cleaning process. The transit cavitation may be generated by an acoustic energy applied for cleaning the substrate 1010. As shown in FIG. 1A and FIG. 1B, the micro jet caused by bubble 1050 implosion occurs above the top of the patterned structures 1030 and is very violent (can reaches a few thousands atmospheric pressures and a few thousands ° C.), which can damage the fine patterned structures 1030 on the substrate 1010, especially when the feature size t shrinks to 70 nm and smaller.

The bubble cavitation damaging patterned structures on the substrate caused by the micro jet generated by bubble implosion has been conquered by controlling the bubble cavitation during the cleaning process. A stable or controlled cavitation on the entire substrate can be achieved to avoid the patterned structures being damaged, which has been disclosed in patent application no. PCT/CN2015/079342, filed on May 20, 2015.

In some case, even though the power intensity of an ultra or mega sonic applied for cleaning the substrate is reduced to a very low level (almost no particle removal efficiency), the damage of patterned structures on the substrate still occurs. The number of the damage is only a few (under 100). However, normally the number of the bubbles in the cleaning process under the ultra or mega sonic assisting process is tens of thousands. The number of the patterned structures damage on the substrate and the number of bubbles are not match. The mechanism of this phenomenon is unknown.

### SUMMARY

According to one aspect of the present invention is to disclose a substrate cleaning method comprising the steps of: placing a substrate on a substrate holder; delivering cleaning liquid onto the surface of the substrate; implementing a pre-treatment process to detach bubbles from the surface of the substrate; and implementing an ultra or mega sonic cleaning process for cleaning the substrate.

According to another aspect of the present invention is to disclose a substrate cleaning apparatus comprising a substrate holder configured to hold the substrate; at least one inlet configured to deliver cleaning liquid onto the surface of the substrate; an ultra or mega sonic device configured to deliver acoustic energy to the cleaning liquid; one or more controllers configured to: control the ultra or mega sonic device with a first power to implement a pre-treatment process to detach bubbles from the surface of the substrate; and control the ultra or mega sonic device with a second power higher than the first power to implement an ultra or mega sonic cleaning process for cleaning the substrate.

According to another aspect of the present invention is to disclose a substrate cleaning apparatus comprising a substrate holder configured to hold the substrate; one or more inlets configured to deliver cleaning liquid onto the surface of the substrate for cleaning the substrate and deliver liquid chemical solution onto the surface of the substrate for implementing a pre-treatment process to detach bubbles from the surface of the substrate; an ultra or mega sonic device configured to deliver acoustic energy to the cleaning liquid for cleaning the substrate.

### BRIEF DESCRIPTION OF THE DRAWINGS

FIG. 1A and FIG. 1B depict a transit cavitation damaging patterned structures on a substrate during cleaning process;

FIG. 2A to FIG. 2D depict the implosion of bubbles attached on the surface of patterned structures on a substrate damaging patterned structures;

FIG. 3A to FIG. 3H depict the mechanism that the implosion of bubbles attached on the surface of patterned structures on a substrate damages patterned structures;

FIG. 4A and FIG. 4B depict exemplary methods for detaching bubbles from the surface of patterned structures on a substrate, wherein the bubbles are attached on the surfaces of the patterned structures and the substrate;

FIG. 5A to FIG. 5C depict an exemplary method for detaching bubbles from the surface of patterned structures on a substrate, wherein the bubbles are attached on impurities;

FIG. 6A to FIG. 6C depict another exemplary method for detaching bubbles from the surface of patterned structures on a substrate, wherein the bubbles are attached on impurities;

FIG. 7A and FIG. 7B depict an exemplary method for detaching bubbles from the surface of patterned structures on a substrate, wherein the bubbles are attached on particles;

FIG. 8A and FIG. 8B depict another exemplary method for detaching bubbles from the surface of patterned structures on a substrate, wherein the bubbles are attached on particles;

FIG. 9 depicts an exemplary method for cleaning substrates according to the present invention;

FIG. 10 depicts another exemplary method for cleaning substrates according to the present invention;

FIG. 11 depicts another exemplary method for cleaning substrates according to the present invention;

FIG. 12 depicts another exemplary method for cleaning substrates according to the present invention; and

FIG. 13A and FIG. 13B depict an exemplary apparatus for cleaning substrates according to the present invention.

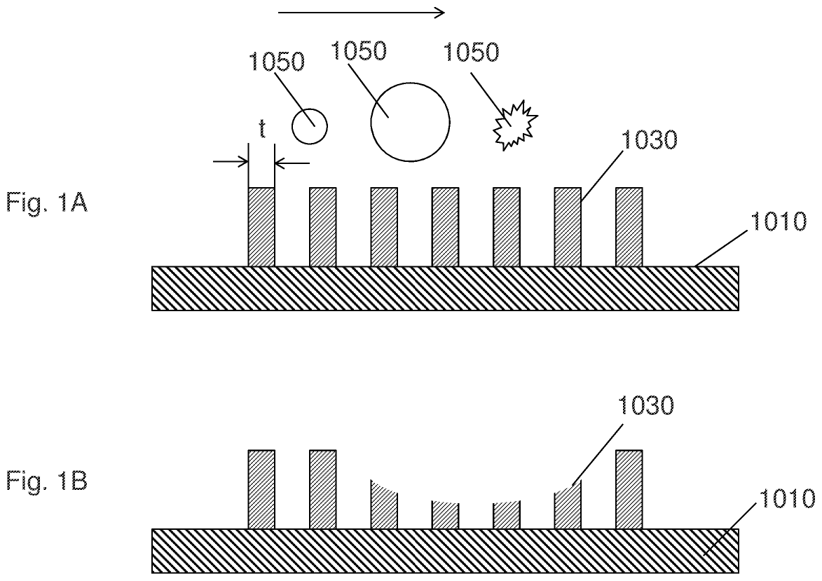

### DETAILED DESCRIPTION

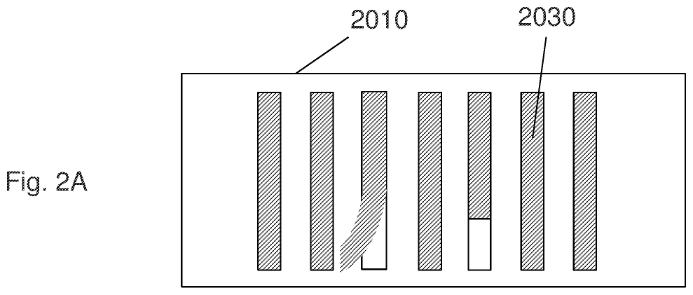

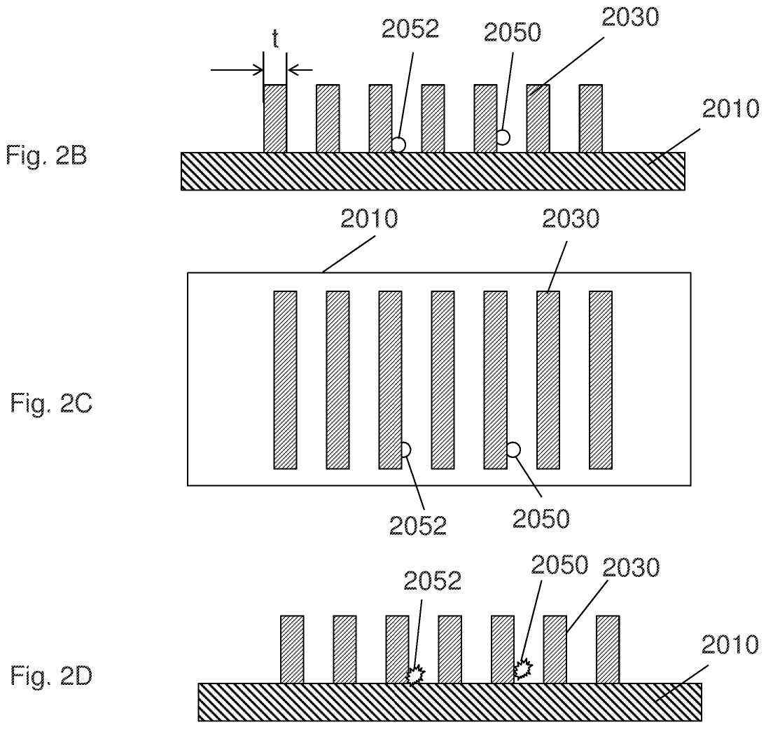

Referring to FIG. 2A, during the ultra or mega sonic assisting substrate cleaning process, there is a phenomenon that even though the power intensity of an ultra or mega sonic applied for cleaning the substrate 2010 is reduced to a very low level (almost no particle removal efficiency), the damage of patterned structures 2030 on the substrate 2010 still occurs. What is more, it is often the case that single wall of the patterned structure 2030 is damaged. FIG. 2A illustrates the damage with two examples. One example is that single wall of the patterned structure 2030 is peeled toward a side. Another example is that a part of single wall of the patterned structure 2030 is removed. Although FIG. 2A illustrates two examples, it should be recognized that other similar damages may happen. What causes these damages?

Referring to FIG. 2B to FIG. 2D, in the substrate cleaning process, small bubbles 2050, 2052 tend to attach on solid surface such as the surface of substrate 2010 or side walls of patterned structures 2030, as shown in FIG. 2B and FIG. 2C. When the bubbles 2050, 2052 are attached on the surface of substrate 2010 or side walls of patterned structures 2030, such as the bubble 2052 attaching on the bottom corner of the patterned structure 2030 and the bubble 2050 attaching on single side wall of the patterned structure 2030, once these bubbles 2050, 2052 implode, the patterned structures 2030 are peeled toward the direction in accord with the direction of bubble implosion force acting on the single side wall from the sub-layer on the substrate 2010 or a part of single side wall of the patterned structure 2030 is removed, as shown in FIG. 2A. Although the implosion is not as intense as the micro jet, however, due to the bubbles 2050, 2052 attaching on the surface of the substrate 2010 and the side walls of the patterned structures 2030, the energy generated by small bubbles implosion can also damage the patterned structures 2030.

Moreover, during a wet process, the small bubbles may coalesce into bigger bubbles. Due to the tendency of bubble attachment on the solid surface, the coalescence on the solid surface such as the surfaces of the patterned structures and the substrate increases the risk of the bubbles implosion happening on the patterned structures, in particular, the critical geometrical portion.

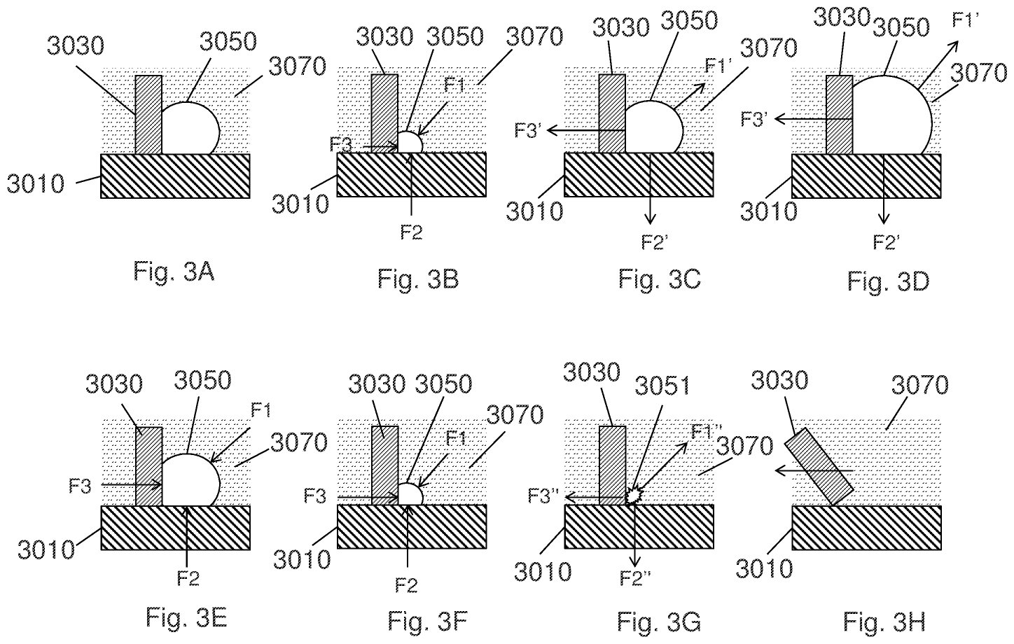

FIG. 3A to FIG. 3H depict the mechanism that the implosion of bubbles attached on a substrate damages patterned structures on the substrate during an ultra or mega sonic assist wet cleaning process according to the present invention. FIG. 3A illustrates cleaning liquid 3070 is delivered onto the surface of a substrate 3010 having patterned structures 3030 and at least one bubble 3050 is attached on the bottom corner of the patterned structure 3030. In a positive ultra or mega sonic working process shown in FIG. 3B, F1 is the ultra or mega sonic pressing force working on the bubble 3050, F2 is the counter force working on the bubble 3050 generated by the side wall of the patterned structure 3030 while the bubble 3050 pressing on the side wall of the patterned structure 3030, and F3 is the counter force working on the bubble 3050 generated by the substrate 3010 while the bubble 3050 pressing on the substrate 3010. In a negative ultra or mega sonic working process shown in FIG. 3C and FIG. 3D, the bubble 3050 is expanding due to the ultra or mega sonic negative force pulling the bubble 3050. In the process of the bubble volume expanding, F1′ is the force of the bubble 3050 pushing the cleaning liquid 3070, F2′ is the force of the bubble 3050 pushing the substrate 3010, and F3′ is the force of the bubble 3050 pushing the side wall of the patterned structure 3030. After the positive ultra or mega sonic and the negative ultra or mega sonic are alternately applied for a number of cycles, the gas temperature inside of bubbles increases higher and higher, the bubble volume grows bigger and bigger, and the bubble implosion 3051 occurs finally, which generates the implosion force F1″ acting on the cleaning liquid 3070, F2″ acting on the substrate 3010, F3″ acting on the side wall of the patterned structure 3030, as shown in FIG. 3G. The implosion force causes the side wall of the patterned structure 3030 being damaged as shown in FIG. 3H.

For avoiding the patterned structures on the substrate being damaged caused by bubble implosion during the ultra or mega sonic assist wet cleaning process, it is preferable to detaching the bubbles from the surfaces of the patterned structures and the substrate before the acoustic energy is applied to the cleaning liquid for cleaning the substrate.

Hereinafter a plurality of methods is disclosed to detach bubbles from the surfaces of the pattern structures and the substrate.

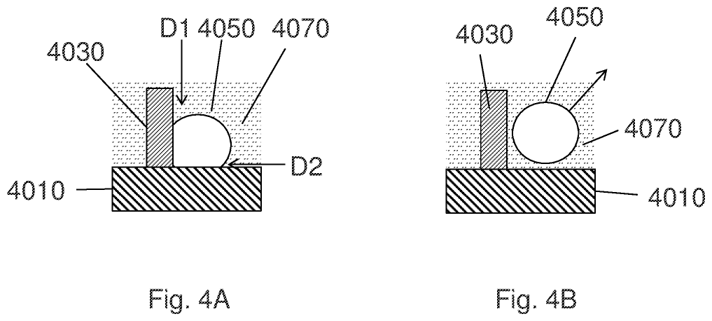

FIG. 4A and FIG. 4B show an embodiment of a substrate pre-treatment for detaching bubbles from the surfaces of patterned structures on a substrate according to the present invention. While cleaning liquid 4070 is delivered onto the surface of a substrate 4010 having patterned structures 4030, at least one bubble 4050 is attached at the bottom corner of the pattern structure 4030 as show in FIG. 4A. Therefore, a bubble detaching pre-treatment process is needed before an ultra or mega sonic cleaning process. In the bubble detaching pre-treatment process, a method such as increasing patterned structures 4030 surface wettability from the directions of D1 and D2 which are respectively along with the solid surface of the patterned structure 4030 and the solid surface of the substrate 4010 or using a minimal mechanical force to interfere from the directions of D1 and D2 is needed to cause the interfaces between the surface of the pattern structure 4030 as well as the surface of the substrate 4010 and the bubble 4050 shrinking gradually, so as to achieve the bubble detached from the pattern structure 4030 and the substrate 4010 at last, as shown in FIG. 4B.

One embodiment of the bubble detaching pre-treatment process according to the present invention is to modify the substrate 4010 surface from hydrophobic to hydrophilic by supplying liquid chemical solution on the substrate 4010 surface, such as supplying liquid chemical solution forming a hydrophilic coating layer on the substrate 4010 surface, or supplying liquid chemical solution like Ozone solution or SCl solution (NH4OH, H2O2, H2O mixture) oxidizing the hydrophobic surface material like Silicon or Ploy Silicon layer to hydrophilic Silicon oxide layer.

One embodiment of the bubble detaching pre-treatment process according to the present invention is to supply the liquid chemical solution containing surfactant, additives or chelating agent on the substrate 4010 surface. The liquid chemical solution containing surfactant, additives or chelating agent is capable of increasing the wettability of the liquid chemical solution on the substrate 4010 surface, so as to detach the bubbles attaching on the surfaces of the patterned structures 4030 and the substrate 4010. The chemical such as carboxyl-containing ethylendiamine tetraacetic acid (EDTA), tetracarboxyl compound-ethylenediamine tetrapropionic (EDTP) acid/salt, etc. is used as a surfactant doped in the liquid chemical solution to increase the wettability of the liquid chemical solution.

Besides, a low power ultra or mega sonic is capable of being combined with the embodiments described above to improve the efficiency of the bubble detaching. The low power ultra or mega sonic generates a minimal mechanical force to contribute to a stable bubble cavitation, so as to generate the mechanical force to detach the bubble 4050 from the surfaces of the patterned structures 4030 and the substrate 4010. The low power ultra or mega sonic is capable of running on a continuous mode (non-pulse mode), and the power density may be, for example, 1 mw/cm²-15 mw/cm². The time duration of applying the low power ultra or mega sonic with continuous mode to the cleaning liquid for detaching the bubbles from the surfaces of the patterned structure 4030 and the substrate 4010 may be, for example, 10 s-60 s. More detailed description of applying the ultra or mega sonic with continuous mode to the cleaning liquid is disclosed in patent application no. PCT/CN2008/073471, filed on Dec. 12, 2008, all of which are incorporated herein by reference. The low power ultra or mega sonic is capable of running on a pulse mode, and the power density may be, for example, 15 mw/cm²-200 mw/cm². The time duration of applying the low power ultra or mega sonic with pulse mode to the cleaning liquid for detaching the bubbles from the surfaces of the patterned structure 4030 and the substrate 4010 may be, for example, 10 s-120 s. More detailed description of applying the ultra or mega sonic with pulse mode to the cleaning liquid is disclosed in patent application no. PCT/CN2015/079342, filed on May 20, 2015, all of which are incorporated herein by reference.

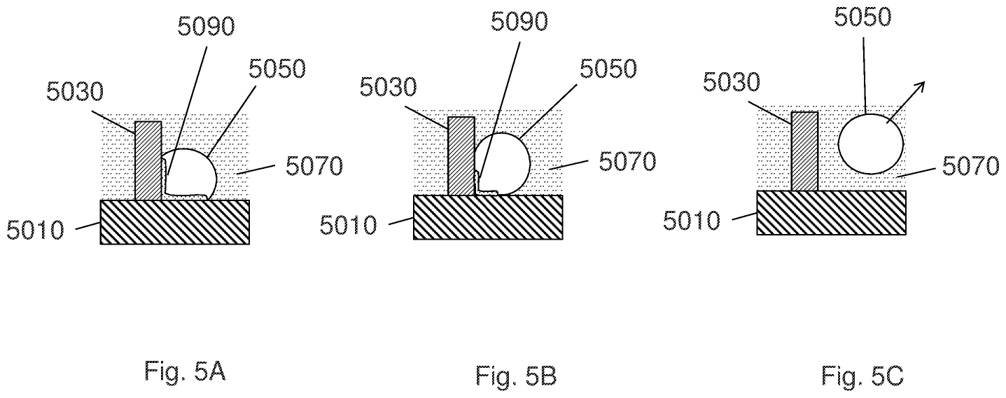

Referring to FIG. 5A to FIG. 5C, one embodiment of the bubble detaching pre-treatment process according to the present invention is to remove impurities such as metal impurities, organic contaminations and polymer residues attached on the substrate surface.

Bubbles 5050 are easy to attach around the impurities 5090 such as metal impurities, organic contaminations and polymer residues attached on the substrate 5010 surface, so that the bubbles 5050 attaching on the surfaces of the patterned structures 5030 and the substrate 5010 have a risk to implode and damage the patterned structures 5030 on the substrate 5010 during the subsequent ultra or mega sonic cleaning process. A pre-treatment method with supplying a liquid chemical solution on the substrate 5010 surface contributes to remove the impurities 5090 such as metal impurities and polymer residues on the substrate 5010 surface before the ultra or mega sonic cleaning process, such as using ozone solution to oxide the surficial polymer residues, and using the high temperature (90 to 150° C.) SPM solution (H2SO4, H2O2 mixture) to carbonize the surficial polymer residues. In another embodiment, the chemical like EDTA is also used for the surface metal ion chelating, so as to remove the metal impurities.

In some case, when the impurities 5090 such as organic contaminations or polymer residues accumulate at the corner of the patterned structure 5030, the bubble 5050 is easy to attach on the impurities 5090 due to the poor wettability of the chemical solution onto the surface of the impurities 5090. It may lead to the damaging implosion on the patterned structure 5030 surface. Two methods are disclosed to remove the impurities 5090 and detach the accumulated bubbles 5050. In one embodiment, a chemical solution is used to remove the impurities 5090 in the pre-treatment step, such as using Ozone or SCl solution to remove the organic contamination as shown in FIG. 5A. The size of the impurities 5090 is shrinking as the chemical solution reacting with the impurities 5090, as shown in FIG. 5B. Since the impurities 5090 are removed from the surfaces of the patterned structure 5030 and the substrate 5010, the wettability of the chemical solution increases to cause the bubble 5050 leaves from the patterned structure 5030 surface, as shown in FIG. 5C.

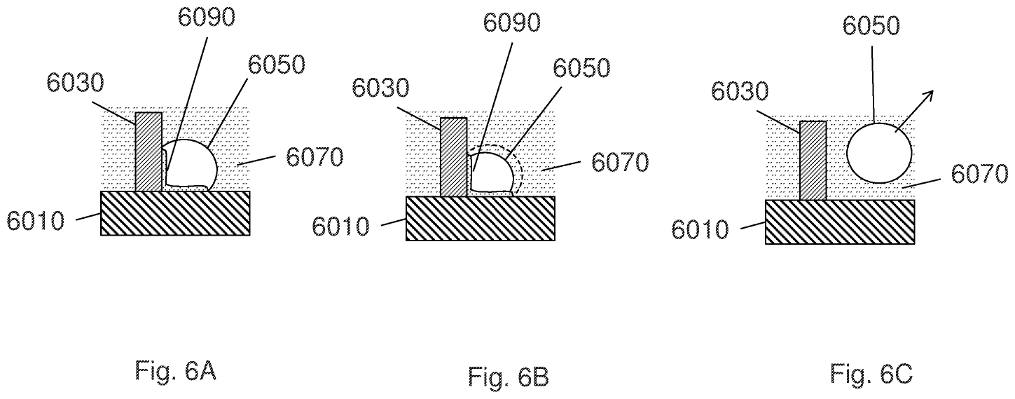

Referring to FIG. 6A to FIG. 6C, in another embodiment according to the present invention, a low power ultra or mega sonic process is used to improve the efficiency of removal the impurities 6090 in the pre-treatment step, such as using Ozone or SCl solution to remove the organic contaminations as shown in FIG. 6A. Due to applying the low power ultra or mega sonic, the size of bubble 6050 is expanding and shrinking alternatively, so as to expose the impurities 6090 to the chemical solution, further reacting with the chemical solution. This process accelerates the reaction efficiency of chemical solution and the impurities 6090. Since the impurities 6090 are removed from the patterned structure 6030 surface, the wettability of the chemical solution increases to cause the bubble 6050 leaves from the patterned structure 6030 surface, as shown in FIG. 6C. The low power ultra or mega sonic is capable of running on a continuous mode (non-pulse mode), and the power density may be, for example, 1 mw/cm²-15 mw/cm². The low power ultra or mega sonic is capable of running on a pulse mode, and the power density may be, for example, 15 mw/cm²-200 mw/cm².

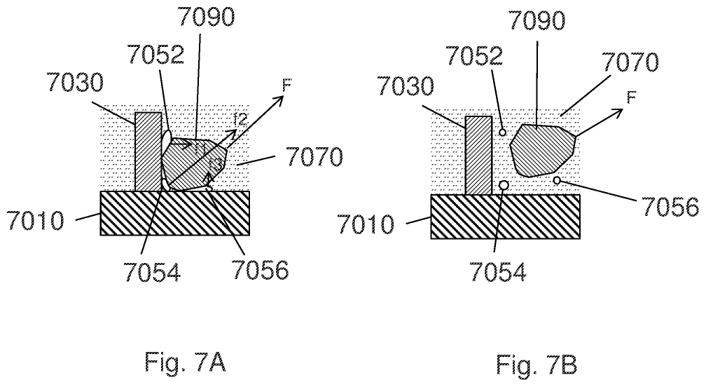

FIG. 7A and FIG. 7B show an embodiment of bubbles being detached from the surface of patterned structures on a substrate. If a particle 7090 is trapped at the corner of the patterned structure 7030 on the substrate 7010, the bubbles 7052, 7054, 7056 are easier to accumulate around the surface of the particle 7090 due to the particle's irregularly geographic shape. The bubbles 7052, 7054, 7056 which are attaching on the surface of the patterned structure 7030 and the surface of the particle 7090 have a risk to implode and damage the patterned structure 7030. Therefore, a particle removal and bubble detaching pre-treatment process is needed before an ultra or mega sonic cleaning process.

As shown in FIG. 7A and FIG. 7B according to the present invention, in the pre-treatment process, the particle 7090 is removed so as to further detach the bubbles 7052, 7054, 7056 from the surface of the patterned structure 7030 and the surface of the substrate 7010. A low power ultra or mega sonic can be applied to the cleaning liquid 7070 to remove the particle 7090 and detach the bubbles 7052, 7054, 7056 from the surface of the patterned structure 7030 and the surface of the substrate 7010 before the subsequent ultra or mega sonic cleaning process. The low power ultra or mega sonic generates bubble cavitation on the bubbles 7052, 7054, 7056. The cavitation of the bubbles 7052, 7054, 7056 generates mechanical forces f1, f2, f3 and the combined force F to push the particle 7090 outwardly, as shown in FIG. 7A. The particle 7090 is lifted up finally, and the cavitation force of the bubbles 7052, 7054, 7056 also generates acoustic agitation for the bubbles 7052, 7054, 7056 being detached from the surface of the patterned structure 7030 and the surface of the substrate 7010. The low power ultra or mega sonic is capable of running on a continuous mode (non-pulse mode), and the power density may be, for example, 1 mw/cm²-15 mw/cm². The low power ultra or mega sonic is capable of running on a pulse mode, and the power density may be, for example, 15 mw/cm²-200 mw/cm².

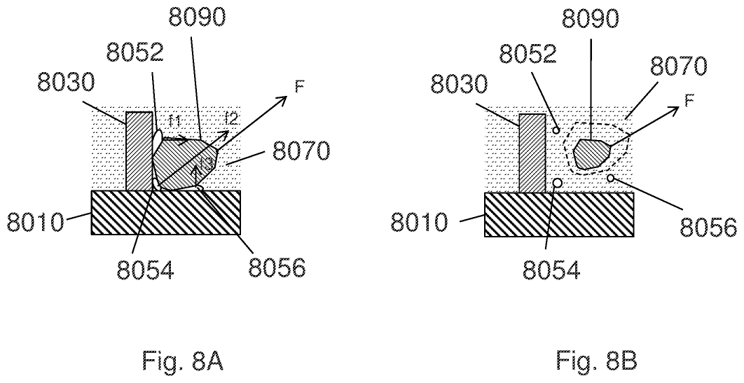

FIG. 8A and FIG. 8B show another embodiment of bubbles being detached from the surface of patterned structures on a substrate according to the present invention. In the pre-treatment process, the particle 8090 is removed so as to further detach the bubbles 8052, 8054, 8056 from the surface of the patterned structure 8030 and the surface of the substrate 8010 by supplying a liquid chemical solution 8070 on the substrate 8010 surface to react or dissolve the particle 8090. The example of the chemical solution is Ozone solution or SCl solution, oxidizing the polymer particles. In this process, a low power ultra or mega sonic process can also be applied to assist the chemical reaction or dissolution before the subsequent ultra or mega sonic cleaning process. The low power ultra or mega sonic generates bubble cavitation on the bubbles 8052, 8054, 8056 that surrounding the particle 8090 trapped at the corner of the patterned structure 8030. The cavitation of bubbles 8052, 8054, 8056 generates the mechanical force f1, f2, f3 and the combined force F to push the particle 8090 outwardly. The liquid chemical solution reaction or dissolution on the particle 8090 combining with the mechanical force of the low power ultra or mega sonic contributes the particle 8090 being lifted up finally, and the bubbles 8052, 8054, 8056 cavitation force also generate the acoustic agitation for the bubbles 8052, 8054, 8056 detaching from the surface of the patterned structure 8030 and the surface of the substrate 8010.

The present invention discloses a substrate cleaning method, comprising the steps of:

placing a substrate on a substrate holder;

delivering cleaning liquid onto the surface of the substrate;

implementing a pre-treatment process to detach bubbles from the surface of the substrate; and

implementing an ultra or mega sonic cleaning process for cleaning the substrate.

The time duration of implementing the pre-treatment process is 5 sec. or more than 5 sec.

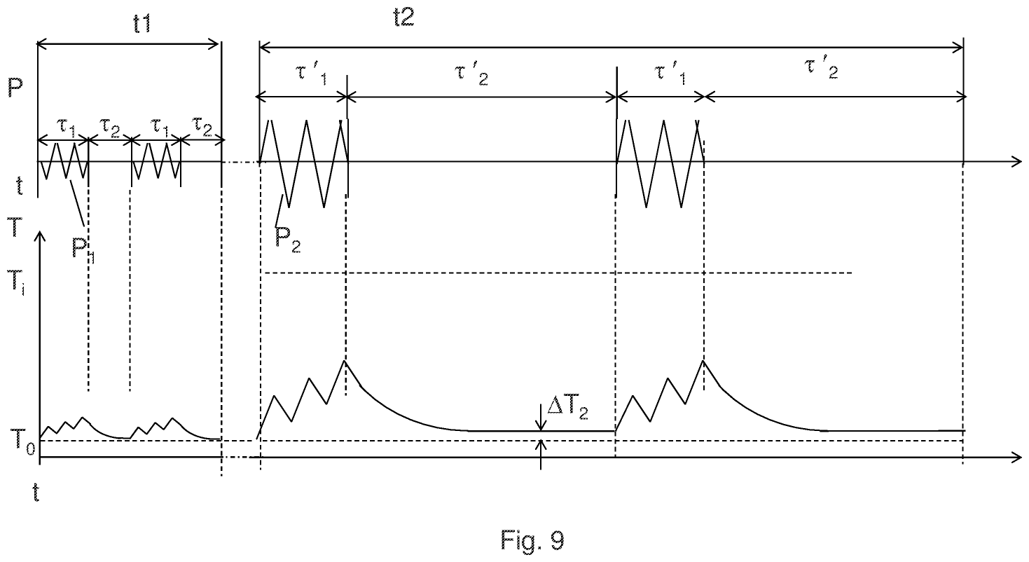

FIG. 9 shows an embodiment of a substrate cleaning method according to the present invention. In the embodiment, an ultra or mega sonic which runs on a pulse mode is applied to implement a pre-treatment process to detach bubbles from the surface of the substrate. The ultra or mega sonic has a first power. The power density may be, for example, 15 mw/cm²-200 mw/cm². The time duration of applying the low power ultra or mega sonic with pulse mode for detaching bubbles may be, for example, 10 s-120 s. After the bubbles are detached from the surface of the substrate, subsequently, an ultra or mega sonic which runs on a pulse mode is applied to implement an ultra or mega sonic cleaning process for cleaning the substrate. The ultra or mega sonic has a second power higher than the first power. The power density may be, for example, 0.2 w/cm²-2 w/cm². The time duration of applying the high power ultra or mega sonic with pulse mode for cleaning the substrate may be, for example, within 600 s.

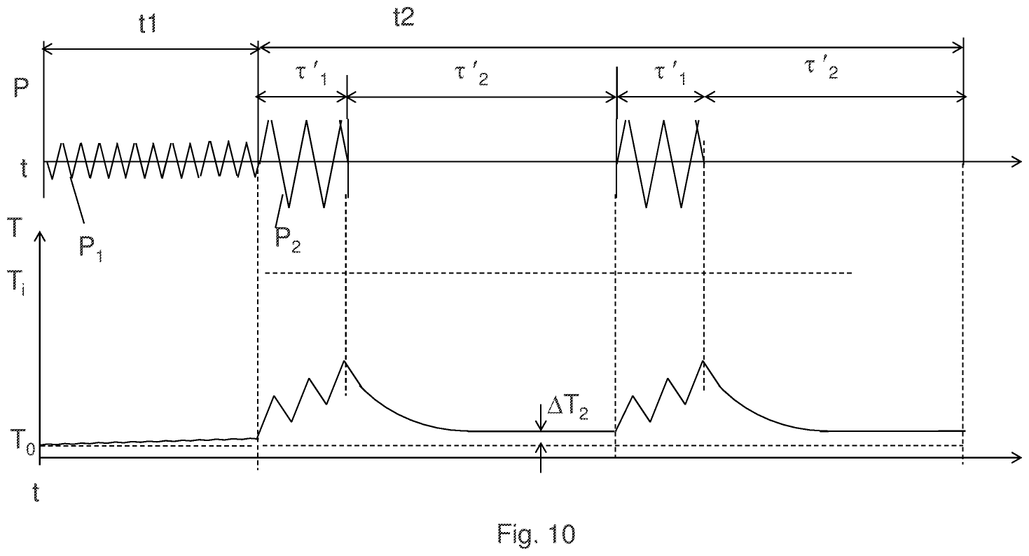

FIG. 10 shows another embodiment of a substrate cleaning method according to the present invention. In the embodiment, an ultra or mega sonic which runs on a continuous mode (non-pulse mode) is applied to implement a pre-treatment process to detach bubbles from the surface of the substrate. The ultra or mega sonic has a first power. The power density may be, for example, 1 mw/cm²-15 mw/cm². The time duration of applying the low power ultra or mega sonic with continuous mode for detaching bubbles may be, for example, 10 s-60 s. After the bubbles are detached from the surface of the substrate, subsequently, an ultra or mega sonic which runs on a pulse mode is applied to implement an ultra or mega sonic cleaning process for cleaning the substrate. The ultra or mega sonic has a second power higher than the first power. The power density may be, for example, 0.2 w/cm²-2 w/cm². The time duration of applying the high power ultra or mega sonic with pulse mode for cleaning the substrate may be, for example, within 600 s.

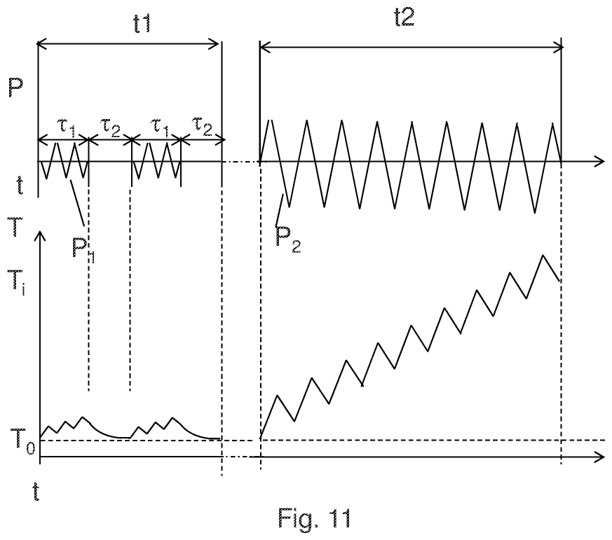

FIG. 11 shows another embodiment of a substrate cleaning method according to the present invention. In the embodiment, an ultra or mega sonic which runs on a pulse mode is applied to implement a pre-treatment process to detach bubbles from the surface of the substrate. The ultra or mega sonic has a first power. The power density may be, for example, 15 mw/cm²-200 mw/cm². The time duration of applying the low power ultra or mega sonic with pulse mode for detaching bubbles may be, for example, 10 s-120 s. After the bubbles are detached from the surface of the substrate, subsequently, an ultra or mega sonic which runs on a continuous mode (non-pulse mode) is applied to implement an ultra or mega sonic cleaning process for cleaning the substrate. The ultra or mega sonic has a second power higher than the first power. The power density may be, for example, 15 mw/cm²-500 mw/cm². The time duration t2 of applying the high power ultra or mega sonic with continuous mode for cleaning the substrate may be, for example, 10 sec.-60 sec. At the t2 duration, the bubble implosion or transit cavitation may happen, however since it happens above the structure, therefore the impact force generated by micro jet may not damage the patterned structure on the substrate.

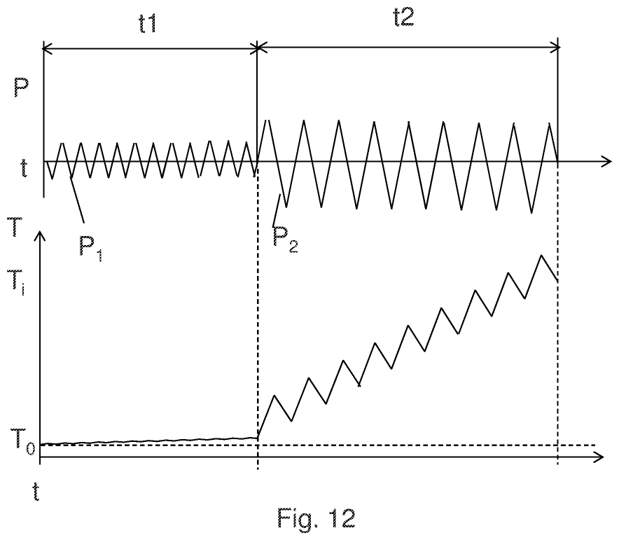

FIG. 12 shows another embodiment of a substrate cleaning method according to the present invention. In the embodiment, an ultra or mega sonic which runs on a continuous mode (non-pulse mode) is applied to implement a pre-treatment process to detach bubbles from the surface of the substrate. The ultra or mega sonic has a first power. The power density may be, for example, 1 mw/cm²-15 mw/cm². The time duration of applying the low power ultra or mega sonic with continuous mode for detaching bubbles may be, for example, 5 sec.-60 sec. After the bubbles are detached from the surface of the substrate, subsequently, an ultra or mega sonic which runs on a continuous mode (non-pulse mode) is applied to implement an ultra or mega sonic cleaning process for cleaning the substrate. The ultra or mega sonic has a second power higher than the first power. The power density may be, for example, 15 mw/cm²-500 mw/cm². The time duration of applying the high power ultra or mega sonic with continuous mode for cleaning the substrate may be, for example, 10 sec.-120 sec.

It should be recognized that the pre-treatment methods for detaching bubbles disclosed in FIG. 4A to FIG. 8B can be applied in or combined with the methods disclosed in FIG. 9 to FIG. 12.

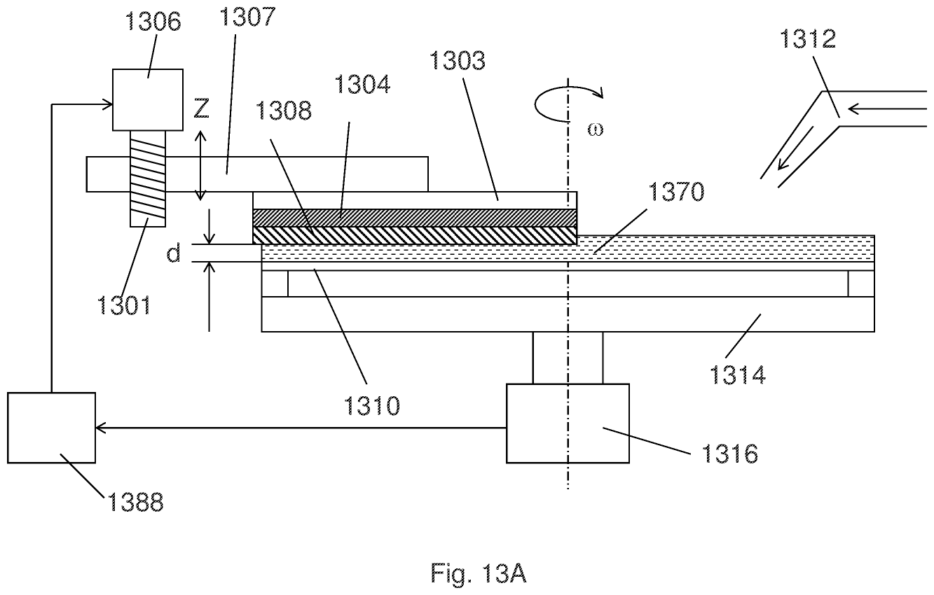

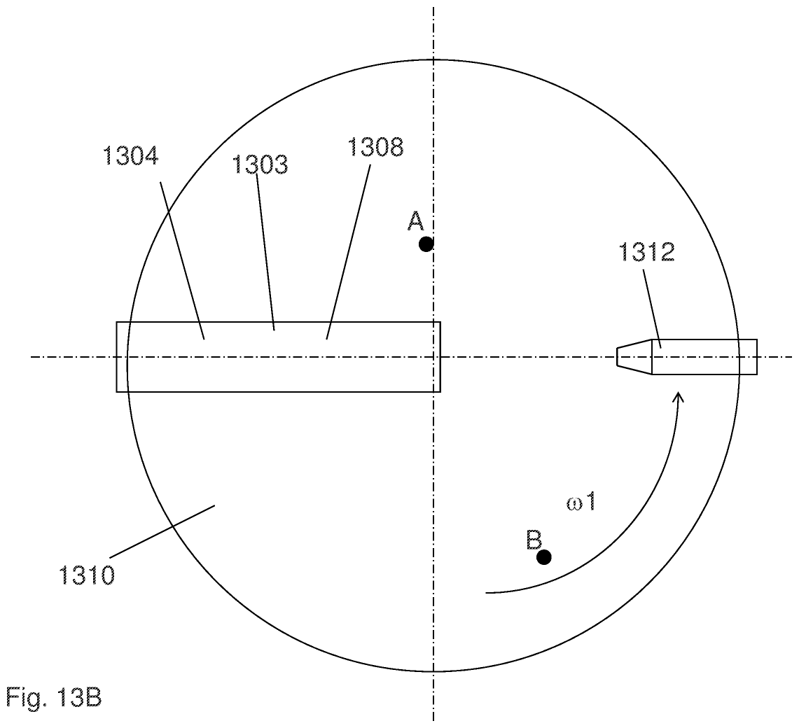

Referring to FIG. 13A and FIG. 13B, a substrate cleaning apparatus according to an embodiment of the present invention is illustrated. FIG. 13A is a cross-sectional view of the substrate cleaning apparatus that includes a substrate holder 1314 holding a substrate 1310, a rotation driving module 1316 driving the substrate holder 1314, and a nozzle 1312 delivering cleaning liquid and liquid chemical solution 1370 to the surface of the substrate 1310. The substrate cleaning apparatus also includes an ultra or mega sonic device 1303 situated above the substrate 1310. The ultra or mega sonic device 1303 further includes a piezoelectric transducer 1304 acoustically coupled to a resonator 1308 in contact with the cleaning liquid. The piezoelectric transducer 1304 is electrically excited to vibrate and resonator 1308 transmits low or high sound energy into the cleaning liquid or the liquid chemical solution. Bubble cavitation generated by the low sound energy causes bubbles being detached from the surface of the substrate 1310. Bubble cavitation generated by the high sound energy causes foreign particles, i.e., contaminants, on the surface of the substrate 1310 to vibrate and break loose therefrom.

Referring again to FIG. 13A, the substrate cleaning apparatus also include an arm 1307 coupled to the ultra or mega sonic device 1303 for moving the ultra or mega sonic device 1303 in a vertical direction Z, thereby changing the liquid film thickness d. A vertical driving module 1306 drives vertical movement of the arm 1307. Both the vertical driving module 1306 and the rotation driving module 1316 are controlled by a controller 1388.

Referring to FIG. 13B which is a top view of substrate cleaning apparatus illustrated in FIG. 13A, the ultra or mega sonic device 1303 covers only a small area of the substrate 1310, which has to rotate to receive uniform sonic energy across the entire substrate 1310. Although only one such ultra or mega sonic device 1303 is illustrated in FIGS. 13A and 13B, in other embodiments, two or more sonic devices may be employed simultaneously or intermittently. Similarly, two or more nozzles 1312 may be employed to deliver respectively cleaning liquid and liquid chemical solution to the surface of the substrate 1310.

In some aspects of the present disclosure, rotation of the substrate holder and application of acoustic energy may be controlled by one or more controllers, for example software programmable control of the equipment. The one or more controllers may comprise one or more timers to control the timing of rotation and/or energy application.

Although the present invention has been described with respect to certain embodiments, examples, and applications, it will be apparent to those skilled in the art that various modifications and changes may be made without departing from the invention.

What is claimed is:

1. A substrate cleaning method, comprising:
placing a substrate on a substrate holder;
delivering cleaning liquid onto the surface of the substrate;
implementing a pre-treatment process to detach bubbles from the surface of the substrate; and
implementing an ultra or mega sonic cleaning process for cleaning the substrate.

2. The method of claim 1, wherein the time duration of implementing the pre-treatment process is 5 sec. or more than 5 sec.

3. The method of claim 1, wherein the step of implementing a pre-treatment process to detach bubbles from the surface of the substrate comprises modifying the substrate surface from hydrophobic to hydrophilic.

4. The method of claim 3, wherein modifying the substrate surface from hydrophobic to hydrophilic is implemented by supplying liquid chemical solution forming a hydrophilic coating layer on the substrate surface.

5. The method of claim 3, wherein modifying the substrate surface from hydrophobic to hydrophilic is implemented by supplying liquid chemical solution oxidizing the hydrophobic substrate surface to hydrophilic oxide layer.

6. The method of claim 1, wherein the step of implementing a pre-treatment process to detach bubbles from the surface of the substrate comprises supplying liquid chemical solution on the substrate surface to increase the wettability of the liquid chemical solution on the substrate surface.

7. The method of claim 1, wherein the step of implementing a pre-treatment process to detach bubbles from the surface of the substrate comprises applying an ultra or mega sonic with a first power to the cleaning liquid to generate a stable bubble cavitation.

8. The method of claim 7, wherein the ultra or mega sonic runs on a continuous mode or pulse mode.

9. The method of claim 1, wherein the step of implementing a pre-treatment process to detach bubbles from the surface of the substrate comprises removing impurities attached on the substrate surface.

10. The method of claim 9, wherein the impurities attached on the substrate surface is removed by using chemical solution.

11. The method of claim 10, further comprising applying an ultra or mega sonic with a first power to the chemical solution to generate a stable bubble cavitation.

12. The method of claim 11, wherein the ultra or mega sonic runs on a continuous mode or pulse mode.

13. The method of claim 1, wherein the step of implementing a pre-treatment process to detach bubbles from the surface of the substrate comprises removing particles and then detaching bubbles from the surface of the substrate.

14. The method of claim 13, wherein an ultra or mega sonic with a first power is applied to the cleaning liquid to remove the particle and detach the bubbles from the surface of the substrate.

15. The method of claim 14, wherein the ultra or mega sonic runs on a continuous mode or pulse mode.

16. The method of claim 13, wherein supplying liquid chemical solution on the substrate surface to react or dissolve the particles.

17. The method of claim 1, wherein the step of implementing an ultra or mega sonic cleaning process for cleaning the substrate comprises applying an ultra or mega sonic with a second power to implement the ultra or mega sonic cleaning process for cleaning the substrate, the ultra or mega sonic runs on a continuous mode or pulse mode.

18. A substrate cleaning apparatus, comprising:
a substrate holder configured to hold the substrate;
at least one inlet configured to deliver cleaning liquid onto the surface of the substrate;
an ultra or mega sonic device configured to deliver acoustic energy to the cleaning liquid;
one or more controllers configured to:
control the ultra or mega sonic device with a first power to implement a pre-treatment process to detach bubbles from the surface of the substrate; and
control the ultra or mega sonic device with a second power higher than the first power to implement an ultra or mega sonic cleaning process for cleaning the substrate.

19. The apparatus of claim 18, wherein the ultra or mega sonic device runs on a continuous mode or pulse mode.

20. The apparatus of claim 18, wherein the inlet supplies liquid chemical solution to modify the substrate surface from hydrophobic to hydrophilic to detach bubbles from the surface of the substrate.

21. The apparatus of claim 18, wherein the inlet supplies liquid chemical solution on the substrate surface to increase the wettability of the liquid chemical solution on the substrate surface to detach bubbles from the surface of the substrate.

22. The apparatus of claim 18, wherein the inlet supplies liquid chemical solution to remove impurities attached on the substrate surface so as to detach bubbles from the surface of the substrate.

23. The apparatus of claim 18, wherein the inlet supplies liquid chemical solution on the substrate surface to react or dissolve particles so as to detach bubbles from the surface of the substrate.

24. A substrate cleaning apparatus, comprising:
a substrate holder configured to hold the substrate;
one or more inlets configured to deliver cleaning liquid onto the surface of the substrate for cleaning the substrate and to deliver liquid chemical solution onto the surface of the substrate for implementing a pre-treatment process to detach bubbles from the surface of the substrate;
an ultra or mega sonic device configured to deliver acoustic energy to the cleaning liquid for cleaning the substrate.

25. The apparatus of claim 24, wherein the time duration of implementing the pre-treatment process is 5 sec. or more than 5 sec.

26. The apparatus of claim 24, wherein the ultra or mega sonic device runs on a continuous mode or pulse mode.
